(19) United States
(12) Patent Application Publication
(10) Pub. No.: US 2006/0048348 A1
(43) Pub. Date: Mar. 9, 2006

(54) CPU clamp

(76) Inventor: Li-Hui Kao, Taipei Shien (TW)

Correspondence Address: PRO-TECHTOR INTERNATIONAL, 20775 Norada Court, Saratoga, CA, 95070-3018, US

(21) Appl. No.: 10/937,230

(22) Filed: Sep. 8, 2004

(51) Int. Cl. H05K 7/20

(52) U.S. Cl. 24/457

(57) ABSTRACT

The present invention is a CPU clamp including an upper clamp and a lower clamp that, by utilizing an elastic body and hooks, a CPU can be easily and swiftly taken out of and placed on a mount, thereby preventing damage to the CPU due to being carelessly hit during operations.

### BACKGROUND OF THE INVENTION

(a) Field of the Invention

The present invention relates to a CPU clamp that a CPU can be easily and swiftly taken out of or placed on a mount, thereby preventing the CPU from damage due to careless hitting during operations.

(b) Description of the Prior Art

Referring to FIG. 1. A CPU 100 is loaded on a handling cell 300 before final application. Referring to FIG. 2. A CPU 100 is placed on a mount 200 having a base plate 201 and connection pins 202, wherein the circuit on the bottom of the CPU 100 connects connection pins 202. To relocate the CPU 100, a conventional way is to use a bare hand to take the CPU 100 out of the handling cell 300 and then place it on the mount 200, which may affect the CPU 100 functioning due to hand sweat or static electricity, besides a risk that the CPU 100 can be dropped, out of a careless operation, that may damage connection pins.

### SUMMARY OF THE INVENTION

The present invention relates to a CPU clamp including a combination of an upper clamp and a lower clamp that, by utilizing a spring force of an elastic body of the upper clamp, a CPU can be easily and swiftly taken out of or placed on a mount, thereby preventing the CPU from damage due to careless hitting during operations.

To enable a further understanding of the said objectives and the technological methods of the invention herein, the brief description of the drawings below is followed by the detailed description of the preferred embodiments.

### BRIEF DESCRIPTION OF THE DRAWING

FIG. 1 shows a perspective view of a CPU on a handling cell.

FIG. 2 shows an exploded elevational view of a CPU on a mount.

FIG. 3 shows a perspective view of the present invention.

FIG. 4 shows an exploded elevational view of the present invention.

FIG. 5 shows an exploded elevational view of a CPU before being clamped by the present invention for placing on a mount.

FIG. 6 shows a perspective view of a CPU being clamped by the present invention and being placed on the mount.

FIG. 7 shows a view of how to detach a CPU from being clamped by the present invention in order to load on a mount.

FIG. 8 shows a perspective view of a CPU loaded on a mount.

FIG. 9 shows a view of how to remove a CPU, being clamped by the present invention, from a mount.

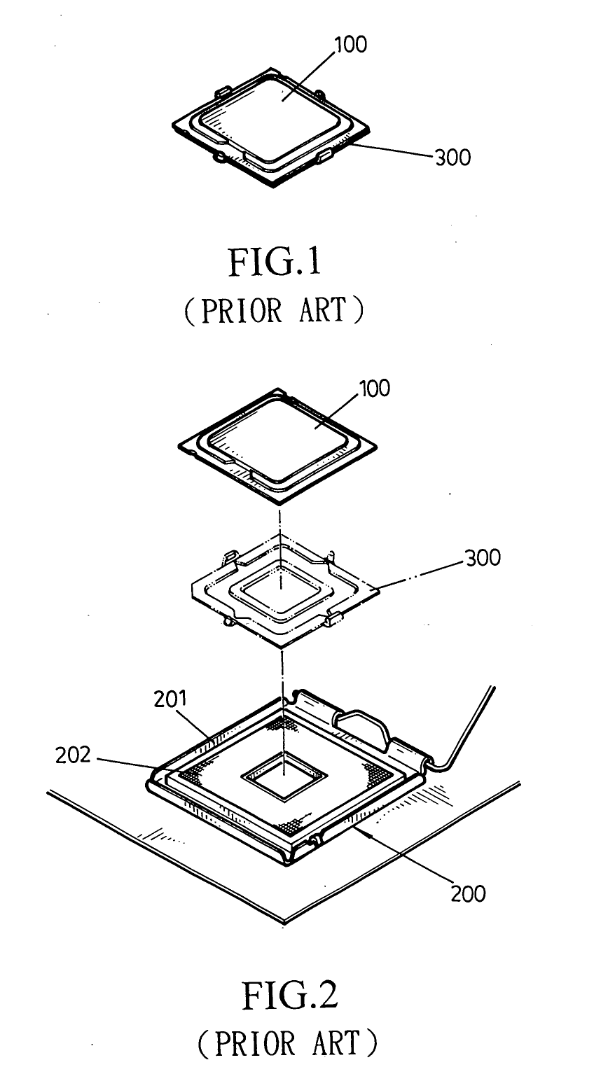

### DETAILED DESCRIPTION OF THE PREFERRED EMBODIMENTS

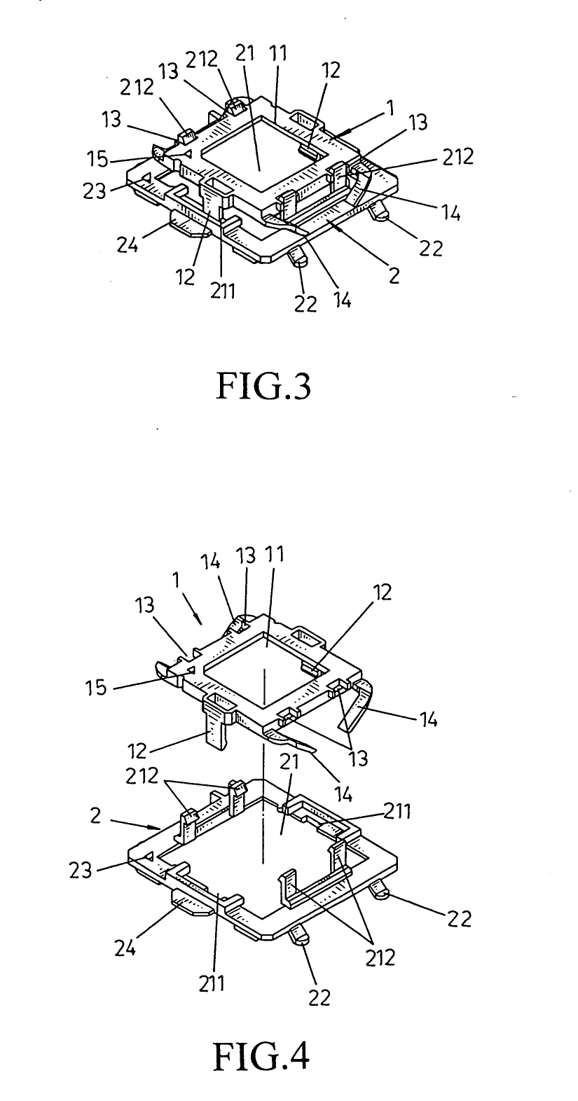

Referring to FIGS. 3 and 4. The present invention is a CPU clamp having an upper clamp 1 and a lower clamp 2 that a CPU 3 can be loaded on or removed from a mount 4, wherein the lower clamp 2, being in a form of a rectangular frame with a hollow 21, having a groove 211 formed on each opposite side of an inner perimeter, a hook 212 formed on each of the other opposite sides thereof, at least a pad 22 formed on each end of each side of an outer perimeter thereof, a mark 23 formed at an comer, and a handle 24 formed on a side; the upper clamp 1, being in a form of a rectangular frame with a hollow 11, having a vertical hook 12 formed on each opposite side of an outer perimeter, two gaps 13 and an elastic body 14 formed on each of the other opposite sides thereof, and a mark 15 corresponding to the mark 23 formed at an corner, wherein, the vertical hook 12 extending downward and reaching the groove 211, each gap 13 being able to be hooked by the hook 212, and each elastic body 14 being able to be pressed downwards to touch against a surface of the lower clamp 2.

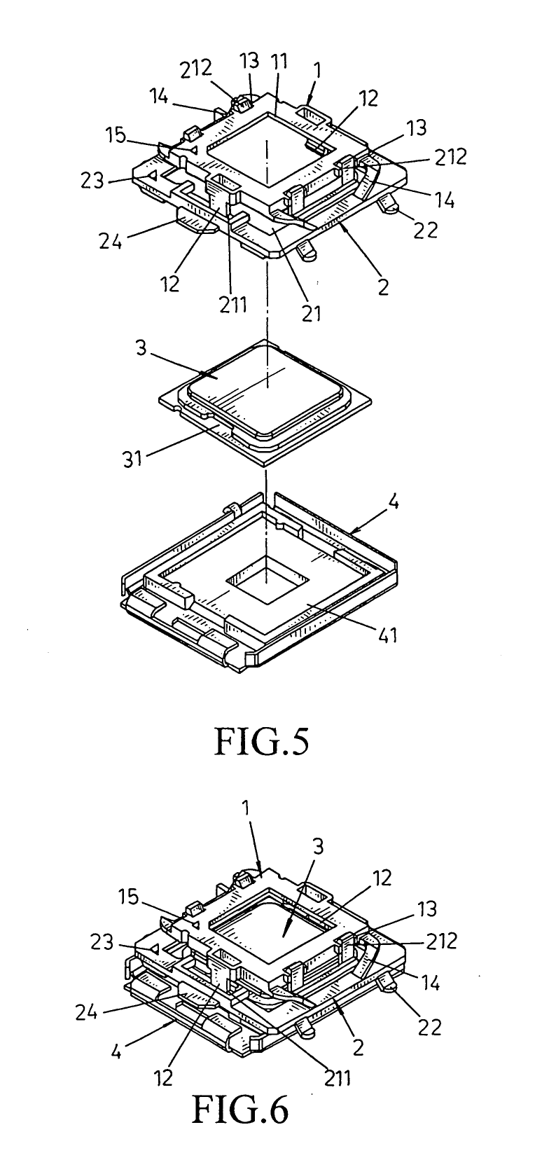

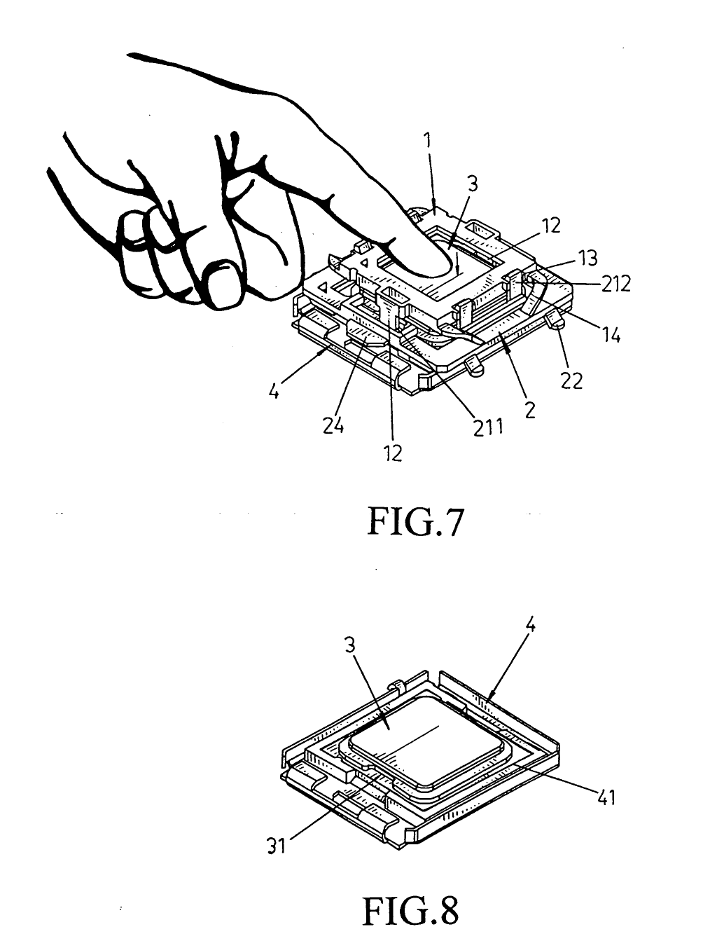

Referring to FIG. 5. The vertical hook 12 of the upper clamp 1 clamps each groove 31 of the CPU 3 to remove the CPU 3. Referring to FIG. 6. The clamped CPU 3 is temporarily loaded on the mount 4. Referring to FIGS. 7 and 8. By pressing the CPU 3 from the hollow 11 with a finger, the CPU 3 thereby being loaded on a base plate 41 of the mount 4.

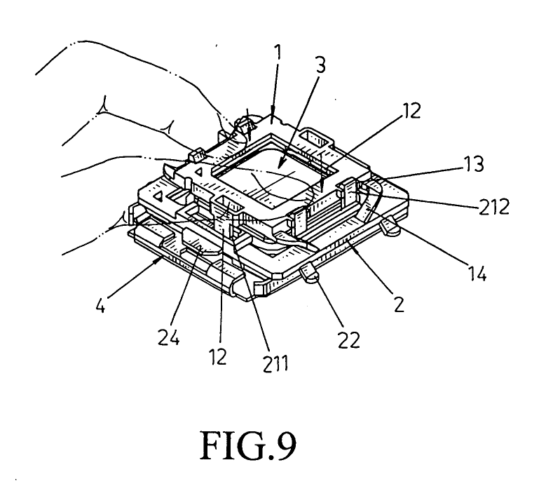

Referring to FIG. 9. After capping the CPU clamp on the CPU 3, imposing a force upon the upper clamp 1 to force elastic bodies 14 moving downward such that each vertical hook 12 extending downward to clamp a groove 31 of the CPU 3, thereby, when releasing the force imposed thereon before, elastic bodies will be moving upward, thereby enabling the CPU 3 being taken out by an upward movement of the upper clamp 1.

In summary, the present invention related to a CPU clamp having an upper clamp and a lower clamp that a CPU can be easily clamped to take out of or place on a mount, thereby preventing being hit out of a careless operation, which may damage the CPU.

It is of course to be understood that the embodiment described herein is merely illustrative of the principles of the invention and that a wide variety of modifications thereto may be effected by persons skilled in the art without departing from the spirit and scope of the invention as set forth in the following claims.

What is claimed is:

1. A CPU clamp comprising an upper clamp and a lower clamp for loading and removing the CPU from a mount, wherein
the lower clamp, having a groove formed on each opposite side of an inner perimeter of a hollow, a hook formed on each side adjoining thereof;
the upper clamp, having a hollow and comprising a vertical hook formed on each opposite side of an outer perimeter, two gaps and an elastic body formed on each of the other opposite sides thereof, wherein,
the vertical hook extending downward and reaching the groove of the lower clamp, each gap being able to be hooked by the hook of the lower clamp, and each elastic body being able to be forced downwards to touch against a surface of the lower clamp.

2. The CPU clamp as recited in claim 1, wherein a mark formed on each upper and lower clamp.

3. The CPU clamp as recited in claim 1, wherein pads formed on each end of each side of an outer perimeter of the lower clamp.

4. The CPU clamp as recited in claim 1, wherein a handle formed on a side of the outer perimeter of the lower clamp.
